(19) United States
(12) Patent Application Publication
(10) Pub. No.: US 2021/0242663 A1
(43) Pub. Date: Aug. 5, 2021

(54) OPTICAL SEMICONDUCTOR ELEMENT AND METHOD OF MANUFACTURING THE SAME AND OPTICAL INTEGRATED SEMICONDUCTOR ELEMENT AND METHOD OF MANUFACTURING THE SAME

(71) Applicant: SUMITOMO ELECTRIC DEVICE INNOVATIONS, INC., Yokohama-shi, Kanagawa (JP)

(72) Inventor: Takayuki WATANABE, Yokohama-shi (JP)

(73) Assignee: SUMITOMO ELECTRIC DEVICE INNOVATIONS, INC., Yokohama-shi, Kanagawa (JP)

(21) Appl. No.: 17/049,212

(22) PCT Filed: Apr. 25, 2019
(86) PCT No.: PCT/JP2019/017644

§ 371 Date: Oct. 20, 2020

(30) Foreign Application Priority Data
Apr. 27, 2018 (JP) 2018-087422

(51) Int. Cl. H01S 5/227; H01S 5/343; H01S 5/32; H01S 5/22

(52) U.S. Cl. CPC H01S 5/2275; H01S 5/222; H01S 5/3211; H01S 5/343

(57) ABSTRACT

An optical semiconductor element including a semiconductor substrate, a first cladding layer of a first conductive type provided on the semiconductor substrate, an active layer provided on the first cladding layer, a second cladding layer of a second conductive type provided on the active layer, a first mesa constituted of a part of the first cladding layer, the active layer, and the second cladding layer, an auxiliary cladding layer of the second conductive type provided on the first mesa, a second mesa constituted of the auxiliary cladding layer, and a semi-insulating layer provided on the first cladding layer and on both sides of the first mesa and both sides of the second mesa, wherein a width of the second mesa is greater than a width of the first mesa.

### TECHNICAL FIELD

The present disclosure relates to an optical semiconductor element and a method of manufacturing the same, and an optical integrated semiconductor element and a method of manufacturing the same.

### BACKGROUND ART

Optical semiconductor elements have been used in optical communication systems (for example, Patent Document 1). To reduce the power consumption, it is required to reduce the series resistance of the optical semiconductor element. On the other hand, for high-speed operation, it is required to reduce the capacitance of the optical semiconductor element.

### PRIOR ART DOCUMENT

### Patent Document

Patent Docuemnt 1: Japanese Patent Application Publication No. H5-55696

### SUMMARY OF THE INVENTION

An optical semiconductor element in accordance with the present disclosure includes: a semiconductor substrate; a first cladding layer of a first conductive type provided on the semiconductor substrate; an active layer provided on the first cladding layer; a second cladding layer of a second conductive type provided on the active layer; a first mesa constituted of a part of the first cladding layer, the active layer, and the second cladding layer; an auxiliary cladding layer of the second conductive type provided on the first mesa; a second mesa constituted of the auxiliary cladding layer; and the semi-insulating layer provided on the first cladding layer and on both sides of the first mesa and both sides of the second mesa, wherein a width of the second mesa is greater than a width of the first mesa.

An optical integrated semiconductor element in accordance with the present disclosure includes: a semiconductor substrate including a first region acting as a laser element and a second region acting as a modulator, the first region and the second region being continuous along an optical axis direction of the laser element; a first cladding layer of a first conductive type provided in the first region and the second region on the semiconductor substrate; a first active layer provided on the first cladding layer and in the first region; a second active layer provided on the first cladding layer and in the second region, the first active layer and the second active layer being continuous along the optical axis direction of the laser element; a second cladding layer of a second conductive type provided on the first active layer; a third cladding layer of a second conductive type provided on the second active layer, the second cladding layer and the third cladding layer being continuous along the optical axis direction of the laser element; a first mesa that is in the first region, and is constituted of a part of the first cladding layer, the first active layer, and the second cladding layer; a second mesa that is provided in the second region such that the second mesa and the first mesa are continuous along the optical axis direction of the laser element, and is constituted of a part of the first cladding layer, the second active layer, and the third cladding layer; an auxiliary cladding layer of the second conductive type provided on the second cladding layer and the third cladding layer; a third mesa that is provided in the first region, and is constituted of the auxiliary cladding layer; and a fourth mesa that is provided in the second region such that the third mesa and the fourth mesa are continuous along the optical axis direction of the laser element, and is constituted of the auxiliary cladding layer; and a semi-insulating layer provided on the first cladding layer and on both sides of the first mesa, both sides of the second mesa, both sides of the third mesa, and both sides of the fourth mesa, wherein a width of the third mesa is greater than a width of the first mesa, and a width of the fourth mesa is greater than a width of the second mesa, and the width of the third mesa is greater than the width of the fourth mesa.

A method of manufacturing an optical semiconductor element in accordance with the present disclosure, includes: a step of forming a first cladding layer of a first conductive type on a semiconductor substrate; a step of forming an active layer on the first cladding layer; a step of forming a second cladding layer of a second conductive type on the active layer; a step of forming a first mesa constituted of the first cladding layer, the active layer, and the second cladding layer by etching a part of the first cladding layer, the active layer, and the second cladding layer; a step of forming a first semi-insulating layer on the first cladding layer and on both sides of the first mesa; a step of causing an auxiliary cladding layer of the second conductive type to be grown on the first mesa and the first semi-insulating layer; a step of forming, on the first mesa, a second mesa having a larger width than the first mesa by etching a part of the first semi-insulating layer and the auxiliary cladding layer; and a step of forming a second semi-insulating layer on the first semi-insulating layer and on both sides of the second mesa, wherein a width of the second mesa is greater than a width of the first mesa.

A method of manufacturing an optical integrated semiconductor element on a semiconductor substrate, the semiconductor substrate including a first region acting as a laser element and a second region acting as a modulator, the first region and the second region being continuous along an optical axis direction of the laser element, includes: a step of forming a first cladding layer of a first conductive type in the first region and the second region on the semiconductor substrate; a step of forming a first active layer on the first cladding layer; a step of forming a second cladding layer of a second conductive type on the first active layer; a step of removing the first active layer and the second cladding layer in the second region; a step of forming a second active layer on the first cladding layer in the second region such that the first active layer and the second active layer are continuous along the optical axis direction of the laser element; a step of forming a third cladding layer of the second conductive type on the second active layer in the second region such that the second cladding layer and the third cladding layer are continuous along the optical axis direction of the laser element; a step of forming, in the first region, a first mesa constituted of the first cladding layer, the first active layer, and the second cladding layer and forming, in the second region, a second mesa constituted of the first cladding layer, the second active layer, and the third cladding such that the first mesa and the second mesa are continuous along the optical axis direction of the laser element, by etching a part of the first cladding layer, the first active layer, the second cladding layer, the second active layer, and the third cladding layer; a step of forming a first semi-insulating layer on the first cladding layer and on both sides of the first mesa and both sides of the second mesa; a step of forming an auxiliary cladding layer of the second conductive type on the first semi-insulating layer and on the first mesa and the second mesa; a step of forming, on the first mesa, a third mesa that is constituted of the auxiliary cladding layer and has a larger width than the first mesa, by etching a part of the first semi-insulating layer and the auxiliary cladding layer in the first region, and forming, on the second mesa, a fourth mesa that is constituted of the auxiliary cladding layer and has a larger width than the second mesa such that the third mesa and the fourth mesa are continuous along the optical axis direction of the laser element, by etching a part of the first semi-insulating layer and the auxiliary cladding layer in the second region; and a step of forming a second semi-insulating layer on the first semi-insulating layer and on both sides of the third mesa and both sides of the fourth mesa, wherein a width of the third mesa is greater than a width of the fourth mesa.

### PROBLEMS TO BE SOLVED BY THE INVENTION

To reduce the series resistance, the width of the cladding layer of the optical semiconductor element is to be increased. On the other hand, to reduce the capacitance, the width of the cladding layer is to be decreased. Thus, it is difficult to achieve both the reduction in series resistance and the reduction in capacitance. Hence, it is an object of the present disclosure to provide an optical semiconductor element and a method of manufacturing the same and an optical integrated semiconductor element and a method of manufacturing the same that are capable of achieving both reduction in series resistance and reduction in capacitance.

### EFFECTS OF THE INVENTION

According to the present disclosure, both reduction in series resistance and reduction in capacitance can be achieved.

### BRIEF DESCRIPTION OF THE DRAWINGS

FIG. 1 is a cross-sectional view illustrating an optical semiconductor element in accordance with a first embodiment;

FIG. 2A is a cross-sectional view illustrating a method of manufacturing the optical semiconductor element, in which epitaxial growth on a semiconductor substrate 10 is conducted;

FIG. 2B is a cross-sectional view illustrating the method of manufacturing the optical semiconductor element, in which an etching mask 15 is formed;

FIG. 2C is a cross-sectional view illustrating the method of manufacturing the optical semiconductor element, in which a semiconductor layer is etched using the etching mask 15 as a mask;

FIG. 2D is a cross-sectional view illustrating the method of manufacturing the optical semiconductor element, in which a semiconductor layer is grown using the etching mask 15 as a mask;

FIG. 3A is a cross-sectional view illustrating the method of manufacturing the optical semiconductor element, in which the etching mask 15 is removed and a semiconductor layer is grown;

FIG. 3B is a cross-sectional view illustrating the method of manufacturing the optical semiconductor element, in which an etching mask 21 is formed and a semiconductor layer is grown;

FIG. 4A is a cross-sectional view illustrating the method of manufacturing the optical semiconductor element, in which the semiconductor layer is etched using the etching mask 21 as a mask;

FIG. 4B is a cross-sectional view illustrating the method of manufacturing the optical semiconductor element, in which a semiconductor layer is grown using the etching mask 21 as a mask;

FIG. 5A presents simulation results of the series resistance of the optical semiconductor element;

FIG. 5B presents simulation results of the capacitance of the optical semiconductor element;

FIG. 6 is a perspective view illustrating an optical integrated semiconductor element in accordance with a second embodiment;

FIG. 7A is a cross-sectional view illustrating a region 31 of the optical integrated semiconductor element in accordance with the second embodiment;

FIG. 7B is a cross-sectional view illustrating a region 33 of the optical integrated semiconductor element of the second embodiment;

FIG. 8A is a perspective view illustrating a method of manufacturing an optical integrated semiconductor element, in which a semiconductor layer is formed on a semiconductor substrate 30;

FIG. 8B is a perspective view illustrating the method of manufacturing the optical integrated semiconductor element, in which the semiconductor layer in the region 33 is etched using an etching mask 35 as a mask;

FIG. 8C is a perspective view illustrating the method of manufacturing the optical integrated semiconductor element, in which a semiconductor layer in the region 33 is grown using the etching mask 35 as a mask;

FIG. 9A is a perspective view illustrating the method of manufacturing the optical integrated semiconductor element, in which an etching mask 41 is formed;

FIG. 9B is a perspective view illustrating the method of manufacturing the optical integrated semiconductor element, in which the semiconductor layer is etched using the etching mask 41 as a mask;

FIG. 9C is a perspective view illustrating the method of manufacturing the optical integrated semiconductor element, in which a semiconductor layer is grown using the etching mask 41 as a mask;

FIG. 10A is a perspective view illustrating the method of manufacturing the optical integrated semiconductor element, in which the etching mask 41 is removed and a semiconductor layer is grown;

FIG. 10B is a perspective view illustrating the method of manufacturing the optical integrated semiconductor element, in which an etching mask 43 is formed;

FIG. 11A is a perspective view illustrating the method of manufacturing the optical integrated semiconductor element, in which the semiconductor layer is etched using the etching mask 43 as a mask; and

FIG. 11B is a perspective view illustrating the method of manufacturing the optical integrated semiconductor element, in which a semiconductor layer is grown using the etching mask 43 as a mask.

### MODES FOR CARRYING OUT THE INVENTION

[Description of Embodiments of the Present Invention]

First, details of embodiments of the present disclosure will be described as listed below.

An embodiment of the present disclosure is (1) an optical semiconductor element including: a semiconductor substrate; a first cladding layer of a first conductive type provided on the semiconductor substrate; an active layer provided on the first cladding layer; a second cladding layer of a second conductive type provided on the active layer; a first mesa constituted of a part of the first cladding layer, the active layer, and the second cladding layer; an auxiliary cladding layer of the second conductive type provided on the first mesa; a second mesa constituted of the auxiliary cladding layer; and the semi-insulating layer provided on the first cladding layer and on both sides of the first mesa and both sides of the second mesa, wherein a width of the second mesa is greater than a width of the first mesa. Both reduction in resistance and reduction in capacitance are achieved by setting the width of the second mesa at an appropriate width.

(2) An optical integrated semiconductor element includes: a semiconductor substrate including a first region acting as a laser element and a second region acting as a modulator, the first region and the second region being continuous along an optical axis direction of the laser element; a first cladding layer of a first conductive type provided in the first region and the second region on the semiconductor substrate; a first active layer provided on the first cladding layer and in the first region; a second active layer provided on the first cladding layer and in the second region, the first active layer and the second active layer being continuous along the optical axis direction of the laser element; a second cladding layer of a second conductive type provided on the first active layer; a third cladding layer of a second conductive type provided on the second active layer, the second cladding layer and the third cladding layer being continuous along the optical axis direction of the laser element; a first mesa that is in the first region, and is constituted of a part of the first cladding layer, the first active layer, and the second cladding layer; a second mesa that is provided in the second region such that the second mesa and the first mesa are continuous along the optical axis direction of the laser element, and is constituted of a part of the first cladding layer, the second active layer, and the third cladding layer; an auxiliary cladding layer of the second conductive type provided on the second cladding layer and the third cladding layer; a third mesa that is provided in the first region, and is constituted of the auxiliary cladding layer; and a fourth mesa that is provided in the second region such that the third mesa and the fourth mesa are continuous along the optical axis direction of the laser element, and is constituted of the auxiliary cladding layer; and a semi-insulating layer provided on the first cladding layer and on both sides of the first mesa, both sides of the second mesa, both sides of the third mesa, and both sides of the fourth mesa, wherein a width of the third mesa is greater than a width of the first mesa, and a width of the fourth mesa is greater than a width of the second mesa, and the width of the third mesa is greater than the width of the fourth mesa. Since the width of the third mesa is large, the resistance of the laser element can be reduced. Since the width of the fourth mesa is small, the capacitance of the modulator can be reduced.

(3) A method of manufacturing an optical semiconductor element, includes: a step of forming a first cladding layer of a first conductive type on a semiconductor substrate; a step of forming an active layer on the first cladding layer; a step of forming a second cladding layer of a second conductive type on the active layer; a step of forming a first mesa constituted of the first cladding layer, the active layer, and the second cladding layer by etching a part of the first cladding layer, the active layer, and the second cladding layer; a step of forming a first semi-insulating layer on the first cladding layer and on both sides of the first mesa; a step of causing an auxiliary cladding layer of the second conductive type to be grown on the first mesa and the first semi-insulating layer; a step of forming, on the first mesa, a second mesa having a larger width than the first mesa by etching a part of the first semi-insulating layer and the auxiliary cladding layer; and a step of forming a second semi-insulating layer on the first semi-insulating layer and on both sides of the second mesa, wherein a width of the second mesa is greater than a width of the first mesa. Both reduction in resistance and reduction in capacitance are achieved by setting the width of the second mesa at an appropriate width.

(4) The first semi-insulating layer may have a level difference on a surface thereof, and a bottom face of the second semi-insulating layer may be in contact with a bottom face of the level difference, and a position of the bottom face of the second semi-insulating layer may be lower than a position of an upper face of the second cladding layer, and higher than a position of a bottom face of the first active layer. Since the first cladding layer becomes wide, the resistance can be reduced. In addition, the area of the part where the first cladding layer and the auxiliary cladding layer face each other becomes small, the capacitance can be reduced.

(5) A method of manufacturing an optical integrated semiconductor element on a semiconductor substrate, the semiconductor substrate including a first region acting as a laser element and a second region acting as a modulator, the first region and the second region being continuous along an optical axis direction of the laser element, includes: a step of forming a first cladding layer of a first conductive type in the first region and the second region on the semiconductor substrate; a step of forming a first active layer on the first cladding layer; a step of forming a second cladding layer of a second conductive type on the first active layer; a step of removing the first active layer and the second cladding layer in the second region; a step of forming a second active layer on the first cladding layer in the second region such that the first active layer and the second active layer are continuous along the optical axis direction of the laser element; a step of forming a third cladding layer of the second conductive type on the second active layer in the second region such that the second cladding layer and the third cladding layer are continuous along the optical axis direction of the laser element; a step of forming, in the first region, a first mesa constituted of the first cladding layer, the first active layer, and the second cladding layer and forming, in the second region, a second mesa constituted of the first cladding layer, the second active layer, and the third cladding such that the first mesa and the second mesa are continuous along the optical axis direction of the laser element, by etching a part of the first cladding layer, the first active layer, the second cladding layer, the second active layer, and the third cladding layer; a step of forming a first semi-insulating layer on the first cladding layer and on both sides of the first mesa and both sides of the second mesa; a step of forming an auxiliary cladding layer of the second conductive type on the first semi-insulating layer and on the first mesa and the second mesa; a step of forming, on the first mesa, a third mesa that is constituted of the auxiliary cladding layer and has a larger width than the first mesa, by etching a part of the first semi-insulating layer and the auxiliary cladding layer in the first region, and forming, on the second mesa, a fourth mesa that is constituted of the auxiliary cladding layer and has a larger width than the second mesa such that the third mesa and the fourth mesa are continuous along the optical axis direction of the laser element, by etching a part of the first semi-insulating layer and the auxiliary cladding layer in the second region; and a step of forming a second semi-insulating layer on the first semi-insulating layer and on both sides of the third mesa and both sides of the fourth mesa, wherein a width of the third mesa is greater than a width of the fourth mesa. Since the width of the third mesa is large, the resistance of the laser element can be reduced. Since the width of the fourth mesa is small, the capacitance of the modulator can be reduced.

(6) The first semi-insulating layer may have a level difference on a surface thereof, and a bottom face of the second semi-insulating layer may be in contact with a bottom face of the level difference, and a position of the bottom face of the second semi-insulating layer may be lower than a position of an upper face of the second cladding layer, and higher than a position of a bottom face of the first active layer. Since the first cladding layer becomes wide, the resistance can be reduced. In addition, since the area of the part where the first cladding layer and the third cladding layer face each other becomes small, the resistance can be reduced.

[Details of Embodiments of the Present Invention]

The following describes specific examples of an optical semiconductor element and a method of manufacturing the same and an optical integrated semiconductor element and a method of manufacturing the same in accordance with embodiments of the present disclosure with reference to drawings. It should be noted that the present disclosure is not limited to these examples but is shown by the claims, and it is intended that all modifications are included in the equivalents of the claims and the scope of the claims.

### First Embodiment

(Optical Semiconductor Element)

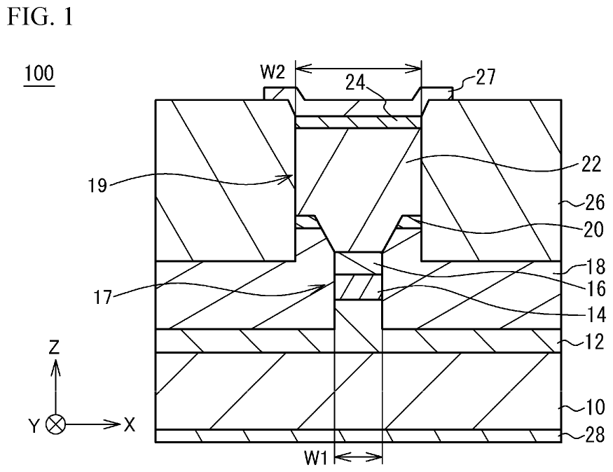

FIG. 1 is a cross-sectional view illustrating an optical semiconductor element 100 in accordance with a first embodiment. FIG. 1 illustrates the cross-section in the XZ plane. The Y direction is the extension direction of mesas 17 and 19, and is the optical axis direction of the optical semiconductor element 100.

As illustrated in FIG. 1, an n-type cladding layer 12 (a first cladding layer) having a protruding shape is provided on a semiconductor substrate 10. An active layer 14 and a p-type cladding layer 16 (a second cladding layer) are provided on a center part of the n-type cladding layer 12, and the n-type cladding layer 12, the active layer 14, and the p-type cladding layer 16 form the mesa 17 (a first mesa). Semi-insulating layers 18 (a first semi-insulating layer) are provided on the n-type cladding layer 12 and on both sides of the mesa 17. The two semi-insulating layers 18 interpose the mesa 17 therebetween, and have a recess in an outer part.

N-type block layers 20 are provided on the two semi-insulating layers 18, and a p-type cladding layer 22 (an auxiliary cladding layer) is provided on the mesa 17. The part that is in contact with the p-type cladding layer 16 of the p-type cladding layer 22 is located between the two semi-insulating layers 18 and between the two n-type block layers 20. A p-type contact layer 24 is provided on the p-type cladding layer 22, and the n-type block layer 20, the p-type cladding layer 22, and the p-type contact layer 24 form the mesa 19 (a second mesa). Semi-insulating layers 26 (a second semi-insulating layer) are provided on the semi-insulating layers 18 and on both sides of the mesa 19. A p-type electrode 27 is provided on the upper faces of the p-type contact layer 24 and the semi-insulating layers 26, and an n-type electrode 28 is provided on the bottom face of the semiconductor substrate 10.

The semiconductor substrate 10 is formed of, for example, n-type indium phosphorus (InP) with a thickness of 100 μm. The n-type cladding layer 12 is formed of, for example, n-type InP with a thickness of 2 μm. The dopants of the semiconductor substrate 10 and the n-type cladding layer 12 are, for example, silicon (Si), and the dopant concentration is, for example, 1×10¹⁸ cm³. The active layer 14 has a multi quantum well (MQW) structure in which indium gallium arsenide phosphorus (InGaAsP) layers doped with zinc (Zn) are stacked and has a thickness of 0.3 μm. In the active layer 14, diffraction gratings (not illustrated) that extend in the Y-axis direction are formed. Modulation signals and bias current are supplied to the p-type electrode 27 and the n-type electrode 28, and light is generated by recombination of carriers in the active layer 14.

The semi-insulating layers 18 and 26 are formed of, for example, InP doped with iron (Fe). The semi-insulating layer 18 has a thickness of, for example, 1.8 μm, and the semi-insulating layer 26 has a thickness of, for example, 3.5 μm. The n-type block layer 20 is formed of, for example, n-type InP doped with Si with a thickness of 0.3 μm. The p-type cladding layers 16 and 22 are formed of, for example, p-type InP doped with Zn, and the dopant concentration is, for example, 5×10¹⁷ cm⁻³. The p-type cladding layer 16 has a thickness of, for example, 0.1 μm, and the p-type cladding layer 22 has a thickness of, for example, 1.5 μm. The p-type contact layer 24 is formed of, for example, p-type indium gallium arsenide (InGaAs) that is doped with Zn and has a thickness of 0.1 μm. The p-type electrode 27 and the n-type electrode 28 are formed of a metal such as gold (Au).

The width W2 of the p-type cladding layer 22 is, for example, 3 μm, and the width W1 of the active layer 14 is, for example, 1.5 μm. That is, the width W2 is greater than the width W1, and in this example, the width W2 is two times the width W1.

(Manufacturing Method)

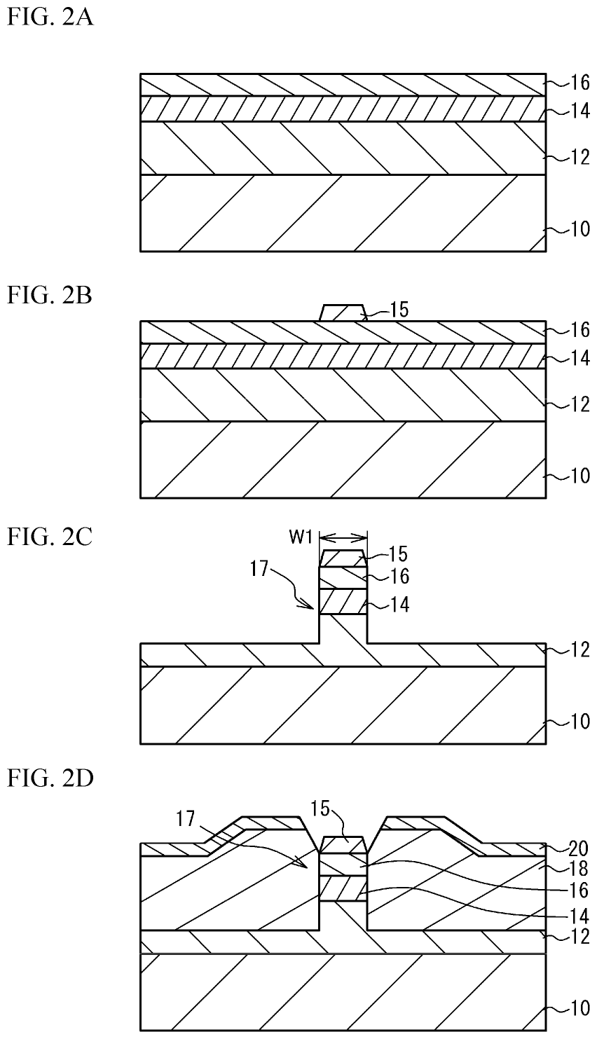

FIG. 2A to FIG. 4B are cross-sectional views illustrating a method of manufacturing the optical semiconductor element 100. As illustrated in FIG. 2A, the n-type cladding layer 12, the active layer 14, and the p-type cladding layer 16 are epitaxially grown in sequence on the semiconductor substrate 10 by, for example, the metal oxide chemical vapor deposition (MOCVD) method. The temperature (the growth temperature) in the MOCVD device is, for example, 620° C., and the growth pressure is, for example, 0.1 atmospheric pressure. The raw material gas of the n-type cladding layer 12 contains, for example, trimethyl indium (TMIn), phosphine (PH₃), and monosilane (SiH₄). The raw material gas of the active layer 14 contains, for example, TMIn, triethyl gallium (TEGa), PH₃, and arsine (AsH₃). The raw material gas of the p-type cladding layer 16 contains, for example, TMIn, PH₃, and dimethyl zinc (DMZ).

As illustrated in FIG. 2B, an etching mask 15 of, for example, silicon dioxide (SiO₂) is formed in a center part of the p-type cladding layer 16. As illustrated in FIG. 2C, the n-type cladding layer 12, the active layer 14, and the p-type cladding layer 16 are dry-etched using the etching mask 15 having, for example, a width of 1.5 μm and a film thickness of 300 nm as a mask. A mixed gas of hydrogen iodine gas and silicon tetrachloride gas is used for dry-etching, and the etching depth is, for example, 1.8 μm. The n-type cladding layer 12, the active layer 14, and the p-type cladding layer 16 under the etching mask 15 form the mesa 17 having the width W1. The n-type cladding layers 12 remaining at both sides of the mesa 17 cover the upper face of the semiconductor substrate 10.

As illustrated in FIG. 2D, by, for example, the MOCVD method, the semi-insulating layers 18 with a thickness of 1.8 μm are grown on the n-type cladding layer 12 and on both sides (on a positive X side and a negative X side) of the mesa 17, and the n-type block layers 20 are then grown on the semi-insulating layers 18. The raw material gas of the semi-insulating layer 18 contains, for example, TMIn, PH₃, and ferrocene (Cp₂Fe). The raw material gas of the n-type block layer 20 contains, for example, TMIn, PH₃, and SiH₄.

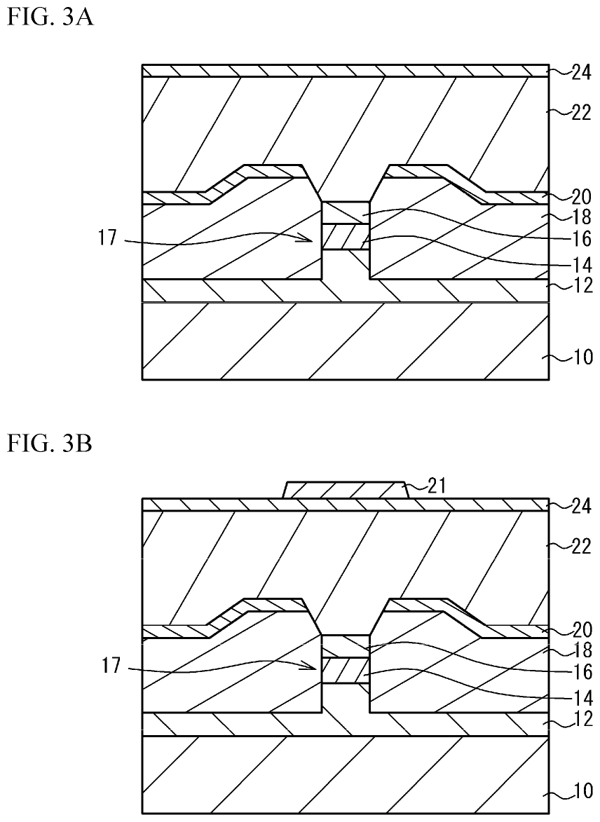

As illustrated in FIG. 3A, the etching mask 15 is removed by immersing the etching mask 15 in, for example, hydrofluoric acid for one minute. Thereafter, by, for example, the MOCVD method, the p-type cladding layer 22 with a thickness of, for example, 3.0 μm is epitaxially grown on the mesa 17 and the n-type block layers 20, and the p-type contact layer 24 is grown on the p-type cladding layer 22. The raw material gas of the p-type cladding layer 22 contains, for example, TMIn, PH₃, and DMZ. The raw material gas of the p-type contact layer 24 contains, for example, TMIn, TEGa, AsH₃, and DMZ. As illustrated in FIG. 3B, an etching mask 21 made of silicon dioxide (SiO₂) having a thickness of, for example, approximately 300 nm is formed on the upper face of the p-type contact layer 24 and in a location overlapping with the mesa 17. The etching mask 21 is formed.

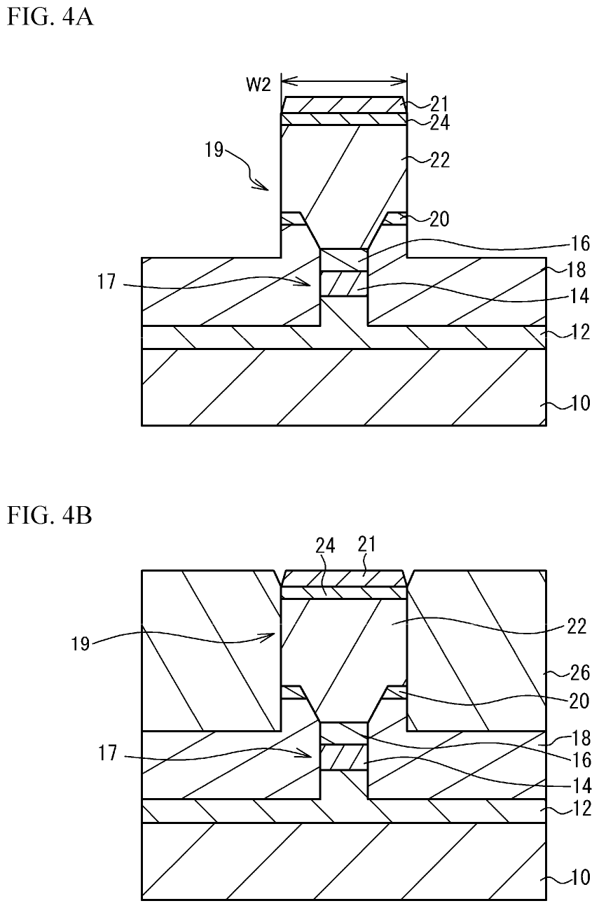

As illustrated in FIG. 4A, the semi-insulating layer 18, the n-type block layer 20, the p-type cladding layer 22, and the p-type contact layer 24 are dry-etched using the etching mask 21 as a mask. A mixed gas of hydrogen iodine gas and silicon tetrachloride gas is used for dry etching, and the etching depth is, for example, 4.0 μm. The semi-insulating layer 18, the n-type block layer 20, the p-type cladding layer 22, and the p-type contact layer 24 under the etching mask 21 form the mesa 19 having the width W2. The semi-insulating layers 18 are exposed to both sides of the mesa 19.

As illustrated in FIG. 4B, the semi-insulating layers 26 with a thickness of 4.0 μm are grown on the semi-insulating layers 18 and on both sides of the mesa 19 by, for example, the MOCVD method. The raw material gas of the semi-insulating layer 26 contains, for example, TMIn, PH₃, and Cp₂Fe. Thereafter, the etching mask 21 is removed by immersing the etching mask 21 in, for example, hydrofluoric acid for one minute, and the p-type electrode 27 and the n-type electrode 28 illustrated in FIG. 1 are formed by, for example, the evaporation method. Through the above process, the optical semiconductor element 100 is formed.

(Series Resistance and Capacitance)

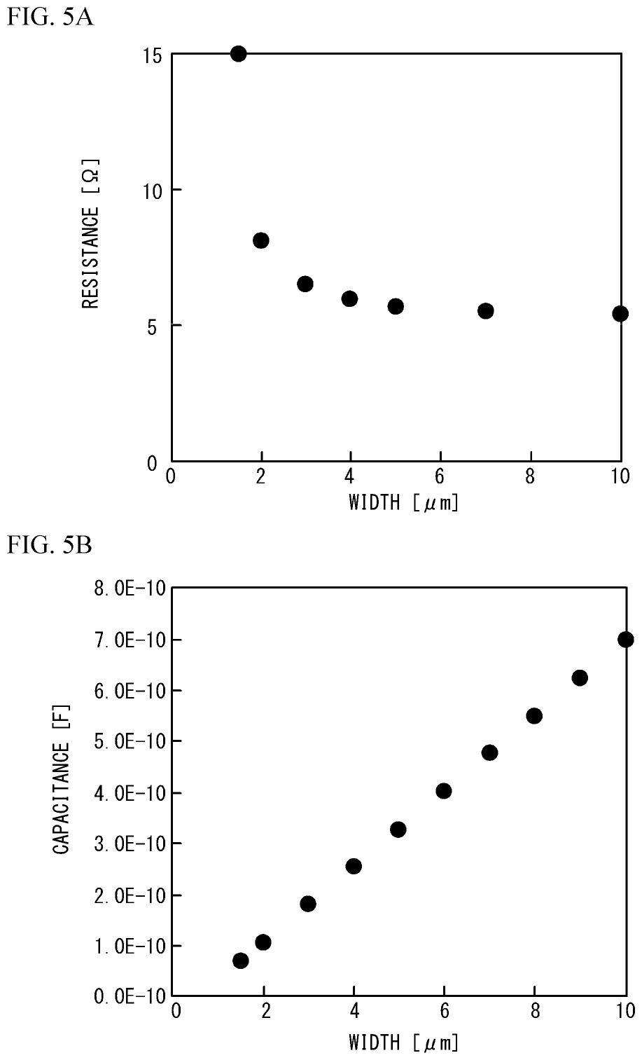

FIG. 5A presents simulation results of the series resistance of the optical semiconductor element 100. FIG. 5B presents simulation results of the capacitance of the optical semiconductor element 100. In these simulations, the series resistance and the capacitance when the width W2 of the p-type cladding layer 22 (the width of the mesa 19) was varied were calculated. The dimensions and the materials other than the width W2 are the same as those described above. That is, the width W1 of the active layer 14 was 1.5 μm, while the width W2 of the p-type cladding layer 22 was varied from 1.5 μm to 10 μm. The length in the Y-axis direction of the optical semiconductor element 100 was 100 μm.

The horizontal axis in FIG. 5A represents the width W2, and the vertical axis represents the series resistance. As presented in FIG. 5A, as the width W2 of the p-type cladding layer 22 decreases, the series resistance of the optical semiconductor element 100 decreases. When the width W2 is 2 μm, the series resistance is less than 10 Ω. When the width W2 is 5 μm, the series resistance is 5.7 Ω. However, since the expansion of electric current in the p-type cladding layer 22 is restrained, the decrease in the series resistance with respect to the increase in the width W2 converges to approximately 5.7 Ω. The horizontal axis in FIG. 5B represents the width W2, and the vertical axis represents the capacitance. As presented in FIG. 5B, as the width W2 decreases, the capacitance of the optical semiconductor element 100 decreases. As seen above, to reduce the resistance, the width W2 is preferably large, while to reduce the capacitance, the width W2 is preferably small.

In the first embodiment, the width W2 of the p-type cladding layer 22 (the width of the mesa 19) is larger than the width W1 of the active layer 14 (the width of the mesa 17). By setting the width W2 at a proper width, both the reduction in resistance and the reduction in capacitance are achieved. The simulation results of FIG. 5A and FIG. 5B reveal that both the reduction in resistance and the reduction in capacitance are achieved by setting the width W2 of the p-type cladding layer 22 at a width equal to or greater than 1.5 times the width W1 of the active layer 14 and equal to or less than 7 times the width W1 of the active layer 14.

Since the series resistance of the optical semiconductor element 100 is reduced, heat generation due to laser oscillation is reduced. Thus, the optical semiconductor element 100 can be driven without a cooler, and the power consumption can be therefore reduced. In addition, since the capacitance of the optical semiconductor element 100 is reduced, high-speed operation becomes possible. Specifically, considering the characteristics of the device, it is preferable that the series resistance is approximately 6 Ω or less (W2 is 4.0 μm or greater) and the capacitance is 200 pF or less (the width W2 is 2 μm or greater and 3.0 μm or less). Furthermore, considering reduction in the size of the optical semiconductor element, it is preferable that the width W2 is approximately 10 μm or less. Here, considering multi-mode oscillation described later and the margin of the process, it is preferable that the width W1 of the active layer 14 is approximately 1.5 μm. As a result, it is preferable that the width W2 is equal to or greater than 1.5 times the width W1 and equal to or less than 7 times the width W1.

The optical semiconductor element 100 includes two semi-insulating layers 18 and 26. As illustrated in FIG. 2D, areas on the both sides of the mesa 17 are filled with the semi-insulating layers 18. As illustrated in FIG. 4A, the mesa 19 having a width larger than that of the mesa 17 is formed by etching the semi-insulating layers 18 and the p-type cladding layer 22, and then, areas on the both sides of the mesas 17 and 19 are filled with the semi-insulating layers 26. The width of the active layer 14 and the width of the p-type cladding layer 22 can be determined by two-step filling described above. Thus, the width W2 of the p-type cladding layer 22 can be made to be larger than the width W1 of the active layer 14.

As illustrated in FIG. 4A, it is preferable that the surface of the semi-insulating layer 18 after etching is located between the bottom face of the p-type cladding layer 22 and the upper face of the n-type cladding layer 12. The bottom face of the semi-insulating layer 26 becomes located between the bottom face of the p-type cladding layer 22 and the upper face of the n-type cladding layer 12. Since the wide n-type cladding layer 12 is located under the semi-insulating layer 18, the series resistance of the n-type cladding layer 12 can be reduced. Furthermore, since the area of the part where the p-type cladding layer 16 faces the n-type cladding layer 12 increases, a large capacitance is generated. In the first embodiment, since the p-type cladding layer 40 is interposed between the semi-insulating layers 18, and thereby, the area of the part where the p-type cladding layer 40 faces the n-type cladding layer 12 decreases, the capacitance decreases.

To reduce the resistance, the width W1 of the active layer 14 may be increased. However, when the width W1 is increased to, for example, 2 μm or greater, a kink occurs due to multi-mode oscillation. To inhibit the kink, it is preferable to make the width W1 small to achieve a current constriction structure.

### Second Embodiment

(Optical Integrated Semiconductor Element)

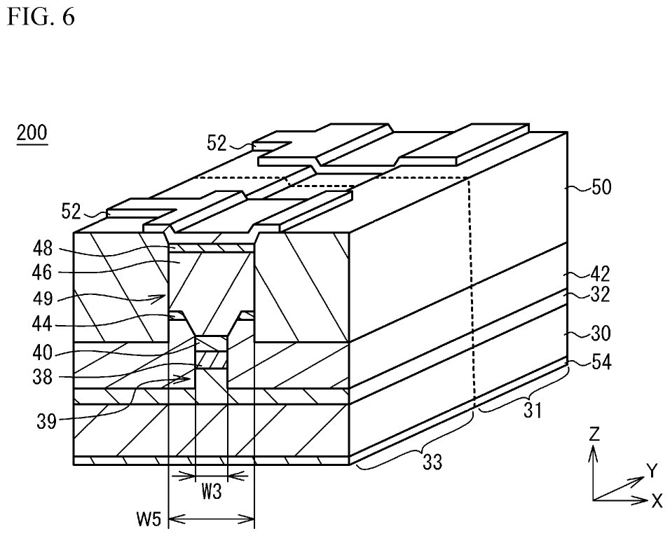

A second embodiment is an exemplary optical integrated semiconductor element 200 in which a modulator and a laser element are integrated. The description of the same components as those of the first embodiment is omitted. FIG. 6 is a perspective view illustrating the optical integrated semiconductor element 200 in accordance with the second embodiment. As illustrated in FIG. 6, the optical integrated semiconductor element 200 includes regions 31 and 33 that are continuous in the Y-axis direction. The region 31 (a first region) is a region acting as a laser element. The region 33 (a second region) is a region that is located closer to the negative Y side than the region 31, and acts as a modulator.

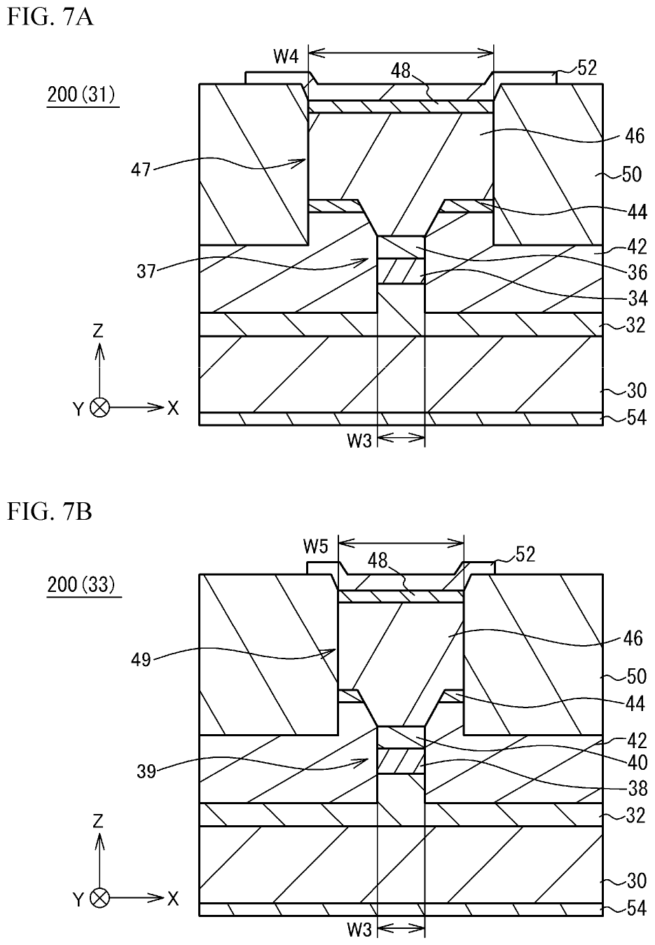

FIG. 7A and FIG. 7B are cross-sectional views illustrating the optical integrated semiconductor element 200. FIG. 7A illustrates the region 31, and FIG. 7B illustrates the region 33. As illustrated in FIG. 7A, the optical integrated semiconductor element 200 includes, in the region 31, a semiconductor substrate 30, an n-type cladding layer 32 (a first cladding layer), an active layer 34 (a first active layer), p-type cladding layers 36 and 46, a semi-insulating layer 42 (a first semi-insulating layer), a semi-insulating layer 50 (a second semi-insulating layer), an n-type block layer 44, a p-type contact layer 48, a p-type electrode 52, and an n-type electrode 54. The n-type cladding layer 32, the active layer 34, and the p-type cladding layer 36 (a second cladding layer) form a mesa 37 (a first mesa). The semi-insulating layer 42, the n-type block layer 44, the p-type cladding layer 46 (an auxiliary cladding layer), and the p-type contact layer 48 form a mesa 47 (a third mesa).

As illustrated in FIG. 7B, the optical integrated semiconductor element 200 includes, in the region 33, the semiconductor substrate 30, the n-type cladding layer 32, an active layer 38 (a second active layer acting as a light absorbing layer), p-type cladding layers 40 and 46, the semi-insulating layers 42 and 50, the n-type block layer 44, the p-type contact layer 48, the p-type electrode 52, and the n-type electrode 54. As illustrated in FIG. 6, the p-type electrodes 52 are formed on the region 31 and the region 33, and are separated from each other. The p-type electrode 52 on the region 31 is wider than the p-type electrode 52 on the region 33. For example, a silicon nitride film (SiN) may be formed on the semi-insulating layer 50 in the separated regions. The n-type cladding layer 32, the active layer 38, and the p-type cladding layer 40 (a third cladding layer) form a mesa 39 (a second mesa). The semi-insulating layer 42, the n-type block layer 44, the p-type cladding layer 46, and the p-type contact layer 48 form a mesa 49 (a fourth mesa).

One or some of the semiconductor layers are different between the region 31 and the region 33. The region 31 includes the active layer 34 and the p-type cladding layer 36, while the region 33 includes the active layer 38 and the p-type cladding layer 40. In the Y-axis direction, the active layer 34 is in contact with the active layer 38, and the p-type cladding layer 36 is in contact with the p-type cladding layer 40. Other semiconductor layers, the p-type electrode 52, and the n-type electrode 54 are provided in both the regions 31 and 33.

The mesas 37 and 39 have the same width W3, and the width W3 is, for example, 1.5 μm. The width W4 of the mesa 47 in the region 31 is, for example, 4 μm, and is larger than the width W3. The width W5 of the mesa 49 in the region 33 is, for example, 3 μm, and is greater than the width W3 and smaller than the width W4.

The semiconductor substrate 30, each semiconductor layer, the p-type electrode 52, and the n-type electrode 54 are formed of the same materials as the corresponding components of the first embodiment, and have the same thicknesses as the corresponding components. The active layers 34 and 38 include diffraction gratings that are not illustrated. The active layer 34 and the active layer 38 may have different compositions from each other. The p-type cladding layer 36 and the p-type cladding layer 40 may have different compositions from each other.

(Manufacturing Method)

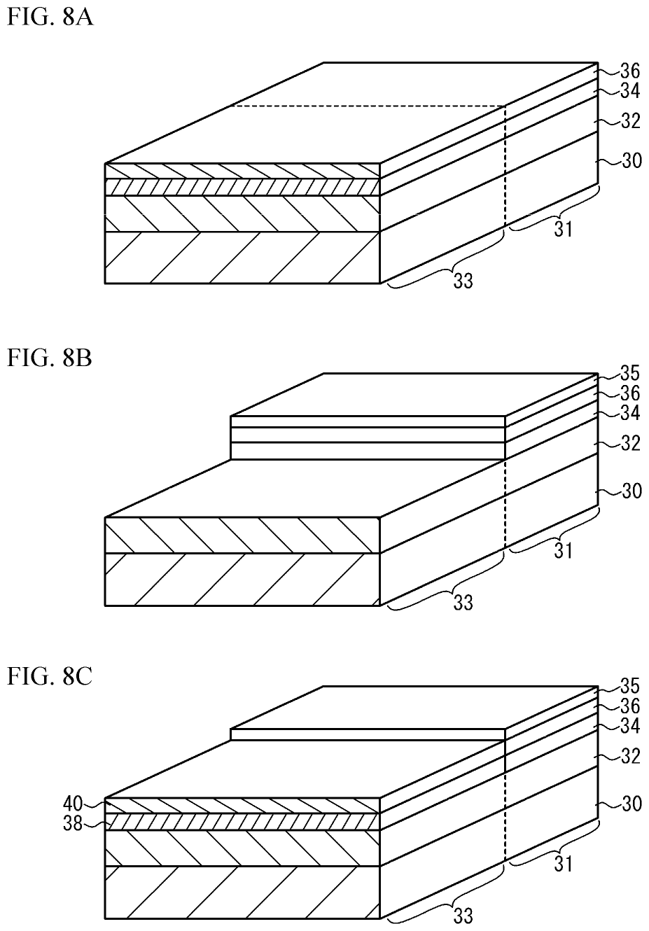

FIG. 8A to FIG. 11B are perspective views illustrating a method of manufacturing the optical integrated semiconductor element 200. The dotted line in each drawing is a virtual line indicating a region between the region 31 and the region 33. The growth temperature, the growth pressure, the raw material gas, and the etching gas identical to those of the first embodiment are used.

As illustrated in FIG. 8A, the n-type cladding layer 32, the active layer 34, and the p-type cladding layer 36 are epitaxially grown in sequence on the semiconductor substrate 30 and in the regions 31 and 33 by, for example, the MOCVD method.

As illustrated in FIG. 8B, an etching mask 35 is provided on the p-type cladding layer 36 in the region 31. Dry etching is performed using a mixed gas of, for example, hydrogen iodine gas and silicon tetrachloride. This removes the active layer 34 and the p-type cladding layer 36 in the region 33 to uncover the n-type cladding layer 32. In the region 31, the active layer 34 and the p-type cladding layer 36 remain. As illustrated in FIG. 8C, the active layer 38 and the p-type cladding layer 40 are epitaxially grown in sequence in the region 33 by, for example, the MOCVD method. The active layer 34 and the active layer 38 are next to each other, and the p-type cladding layer 36 and the p-type cladding layer 40 are next to each other.

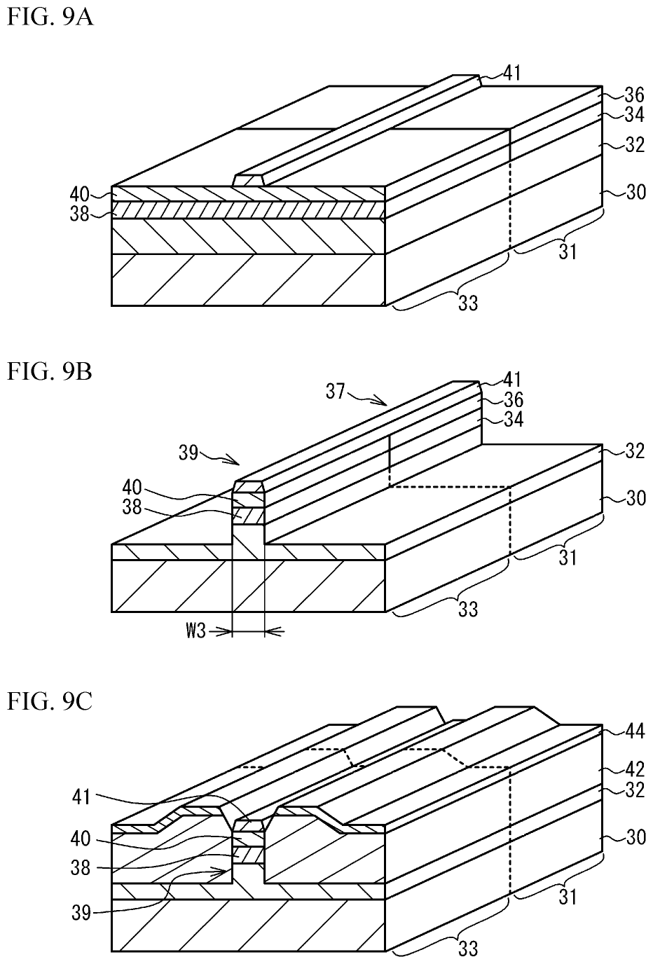

As illustrated in FIG. 9A, the etching mask 41 that is made of, for example, silicon dioxide (SiO₂) and extends to the regions 31 and 33 is formed in the center parts of the p-type cladding layers 36 and 40. For example, the width is 1.5 μm, and the film thickness is approximately 300 nm. As illustrated in FIG. 9B, the n-type cladding layer 32, the active layers 34 and 38, and the p-type cladding layers 36 and 40 are dry-etched using the etching mask 41 as a mask. This process forms the mesa 37 in the region 31 and the mesa 39 in the region 33. The mesas 37 and 39 are continuous in the Y-axis direction. As illustrated in FIG. 9C, by, for example, the MOCVD method, the semi-insulating layers 42 are grown on the n-type cladding layer 32 and on both sides of the mesas 37 and 39, and the n-type block layers 44 are grown on the semi-insulating layers 42.

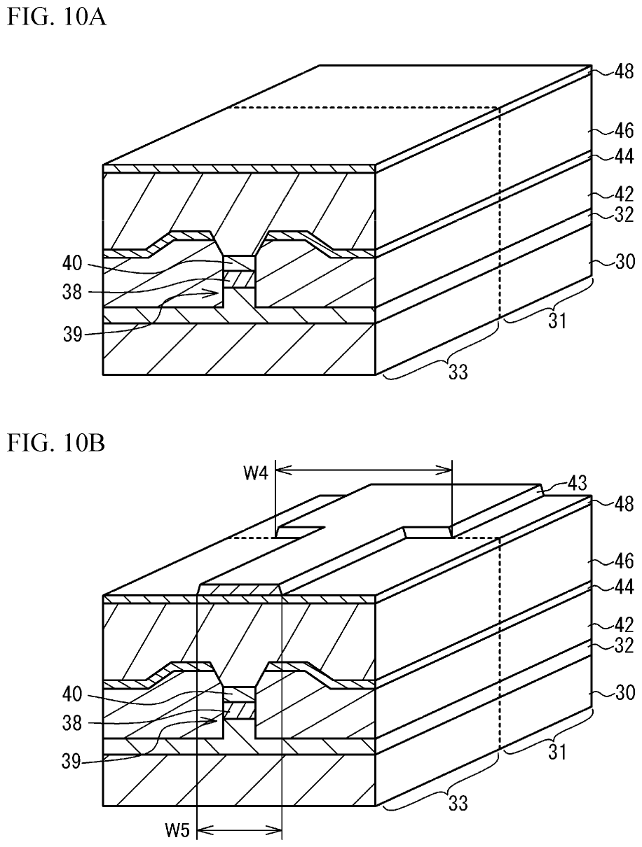

As illustrated in FIG. 10A, the etching mask 41 is removed. Thereafter, by, for example, the MOCVD method, the p-type cladding layer 46 is epitaxially grown on the mesas 37 and 39 and the n-type block layer 44, and the p-type contact layer 48 is grown on the p-type cladding layer 46. As illustrated in FIG. 10B, an etching mask 43 made of, for example, silicon dioxide (SiO₂) is formed on the upper face of the p-type contact layer 48 and in the location overlapping with the mesas 37 and 39. The film thickness is approximately 300 nm. The width of the etching mask 43 in the region 33 is W5, and the width in the region 33 is W4.

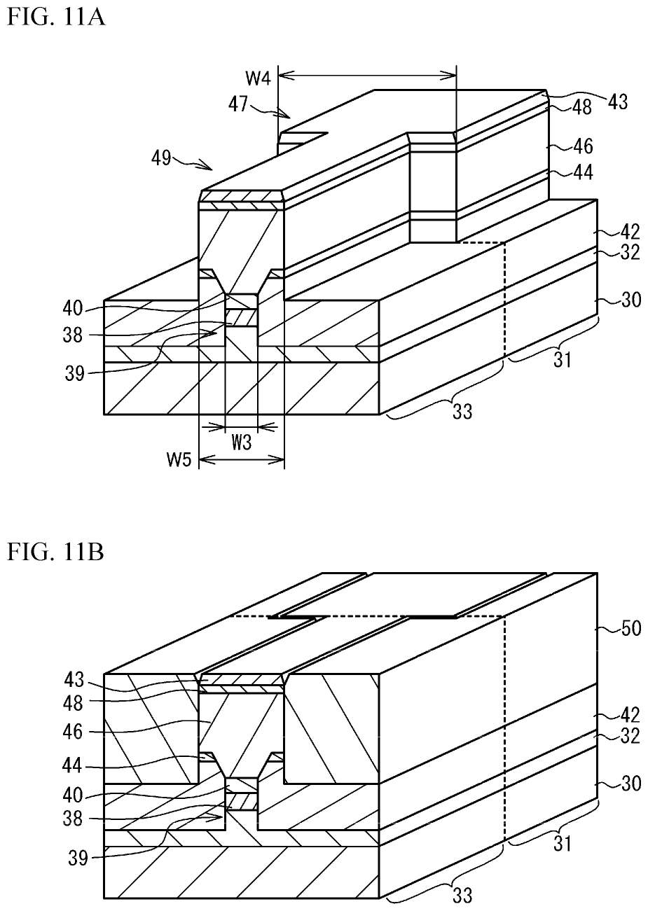

As illustrated in FIG. 11A, dry-etching is performed using the etching mask 43 as a mask. This forms the mesa 47 having the width W5 in the region 31 and the mesa 49 having the width W4 in the region 33. The mesas 47 and 49 are continuous in the Y-axis direction. As illustrated in FIG. 11B, the semi-insulating layers 50 are grown on the semi-insulating layers 42 and on both sides of the mesas 47 and 49 by, for example, the MOCVD method. Thereafter, the etching mask 43 is removed by immersing the etching mask 43 in, for example, hydrofluoric acid for one minute, and the p-type electrode 52 and the n-type electrode 54 illustrated in FIG. 6 to FIG. 7B are formed by, for example, the evaporation method. Through the above process, the optical integrated semiconductor element 200 is formed.

In the second embodiment, the width of the p-type cladding layer 46 is greater than the widths W3 of the active layers 34 and 38. The width W4 of the p-type cladding layer 46 in the region 31 (the width of the mesa 47) is greater than the width W5 in the region 33 (the width of the mesa 49). Thus, the series resistance in the region 31 decreases, and the capacitance in the region 33 decreases. The optical integrated semiconductor element 200 acts as an element in which a laser element having a low resistance and a modulator having a low capacitance are integrated. As a result, the reduction in power consumption is possible and high-speed operation is possible.

According to the simulation presented in FIG. 5A and FIG. 5B, it is preferable that the widths W4 and W5 are equal to or greater than 1.5 times, or equal to or greater than 2 times the width W3 of the active layer 34, and equal to or less than 5 times, or equal to or less than 7 times the width W3 of the active layer 34. In addition, it is preferable that the width W4 in the region 31 is equal to or greater than 2 times the width W5 in the region 33 and equal to or less than 5 times the width W5 in the region 33. Specifically, as described in paragraph 0027, it is preferable that the width W4 of the region 31 is 4.0 μm or greater and 10 μm or less, and the width W5 in the region 33 is 2 μm or greater and 3.0 μm or less. This configuration enables to reduce the resistance of the laser element and reduce the capacitance of the modulator.

The optical integrated semiconductor element 200 includes the two semi-insulating layers 42 and 50. As illustrated in FIG. 7A and FIG. 7B, areas on both sides of the mesas 37 and 39 are filled with the semi-insulating layers 42. The mesa 47 having a larger width than the mesa 37 is formed and the mesa 49 having a larger width than the mesa 39 is formed by etching the semi-insulating layers 42 and the p-type cladding layers 46. Areas on both sides of the mesas 47 and 49 are filled with the semi-insulating layers 50. The width of the active layer and the width of the p-type cladding layer can be determined by two-step filling described above. The width of the p-type cladding layer 46 in the region 31 can be made to be W5, and the width in the region 33 can be made to be W4. In addition, the widths W4 and W5 can be made to be greater than the width W3 of the active layer.

As illustrated in FIG. 11A, it is preferable that the surface of the semi-insulating layer 42 after etching is located between the bottom face of the p-type cladding layer 46 and the upper face of the n-type cladding layer 32. The bottom face of the semi-insulating layer 50 becomes located between the bottom face of the p-type cladding layer 46 and the upper face of the n-type cladding layer 32. Since the wide n-type cladding layer 32 is located under the semi-insulating layer 42, the series resistance of the n-type cladding layer 32 can be reduced. In addition, since the p-type cladding layer 46 is interposed between the semi-insulating layers 50, and the area of the part where the p-type cladding layer 46 faces the n-type cladding layer 32 decreases, the capacitance decreases.

To reduce the resistance, the width W3 of the active layer 34 in the region 31 may be increased. However, when the width W3 is increased to, for example, 2 μm or greater, a kink is caused by multi-mode oscillation. To inhibit the kink, it is preferable to decrease the width W3 to achieve a current constriction structure.

As illustrated in FIG. 11B, it is preferable that the optical integrated semiconductor element 200 is formed so as to be electrically separated from other devices by the semi-insulating layers 42 and 50. This structure eliminates the need for forming a separation mesa, thereby simplifying the process. In addition, compared with a semi-insulated planer buried hetero structure (SIPBH structure), the optical integrated semiconductor element 200 is electrically separated by the semi-insulating layers 42 and 50, thereby, being excellent in preventing deterioration due to applying of current after the forming of the element. It is particularly effective that the semi-insulating layers 42 and 50 are formed across both the regions 31 and 33.

In the first and second embodiments, the conductive type (a first conductive type) of the cladding layer located lower than the active layer is an n-type, and the conductive type (a second conductive type) of the cladding layer located higher than the active layer is a p-type. However, the conductive type may be changed. In the first and second embodiments, the semiconductor substrate and the semiconductor layer may be formed of compound semiconductor other than those described above. In addition, resin such as polyimide or other semi-insulating materials may be used as the semi-insulating layer. The n-type block layer, which is a semiconductor, is grown on the lower semi-insulating layers 18 and 42. To improve the crystal quality and the insulation reliability, it is preferable that the semi-insulating layer is made of semiconductor. Ruthenium (Ru)-doped InP may be used for the semi-insulating layer instead of Fe-doped InP.

1. An optical semiconductor element comprising:
a semiconductor substrate;
a first cladding layer of a first conductive type provided on the semiconductor substrate;
an active layer provided on the first cladding layer;
a second cladding layer of a second conductive type provided on the active layer;
a first mesa constituted of a part of the first cladding layer, the active layer, and the second cladding layer;
an auxiliary cladding layer of the second conductive type provided on the first mesa;
a second mesa constituted of the auxiliary cladding layer; and
a semi-insulating layer provided on the first cladding layer and on both sides of the first mesa and both sides of the second mesa,
wherein a width of the second mesa is greater than a width of the first mesa.

2. An optical integrated semiconductor element comprising:
a semiconductor substrate including a first region acting as a laser element and a second region acting as a modulator, the first region and the second region being continuous along an optical axis direction of the laser element;
a first cladding layer of a first conductive type provided in the first region and the second region on the semiconductor substrate;
a first active layer provided on the first cladding layer and in the first region;
a second active layer provided on the first cladding layer and in the second region, the first active layer and the second active layer being continuous along the optical axis direction of the laser element;
a second cladding layer of a second conductive type provided on the first active layer;
a third cladding layer of a second conductive type provided on the second active layer, the second cladding layer and the third cladding layer being continuous along the optical axis direction of the laser element;
a first mesa that is in the first region, and is constituted of a part of the first cladding layer, the first active layer, and the second cladding layer;
a second mesa that is provided in the second region such that the second mesa and the first mesa are continuous along the optical axis direction of the laser element, and is constituted of a part of the first cladding layer, the second active layer, and the third cladding layer;
an auxiliary cladding layer of the second conductive type provided on the second cladding layer and the third cladding layer;
a third mesa that is provided in the first region, and is constituted of the auxiliary cladding layer; and
a fourth mesa that is provided in the second region such that the third mesa and the fourth mesa are continuous along the optical axis direction of the laser element, and is constituted of the auxiliary cladding layer; and
a semi-insulating layer provided on the first cladding layer and on both sides of the first mesa, both sides of the second mesa, both sides of the third mesa, and both sides of the fourth mesa, wherein
a width of the third mesa is greater than a width of the first mesa, and a width of the fourth mesa is greater than a width of the second mesa, and
the width of the third mesa is greater than the width of the fourth mesa.

3. A method of manufacturing an optical semiconductor element, the method comprising:
a step of forming a first cladding layer of a first conductive type on a semiconductor substrate;
a step of forming an active layer on the first cladding layer;
a step of forming a second cladding layer of a second conductive type on the active layer;
a step of forming a first mesa constituted of the first cladding layer, the active layer, and the second cladding layer by etching a part of the first cladding layer, the active layer, and the second cladding layer;
a step of forming a first semi-insulating layer on the first cladding layer and on both sides of the first mesa;
a step of causing an auxiliary cladding layer of the second conductive type to be grown on the first mesa and the first semi-insulating layer;
a step of forming, on the first mesa, a second mesa having a larger width than the first mesa by etching a part of the first semi-insulating layer and the auxiliary cladding layer; and
a step of forming a second semi-insulating layer on the first semi-insulating layer and on both sides of the second mesa, wherein
a width of the second mesa is greater than a width of the first mesa.

4. The method of manufacturing the optical semiconductor element according to claim 3, wherein
the first semi-insulating layer has a level difference on a surface thereof, and a bottom face of the second semi-insulating layer is in contact with a bottom face of the level difference, and
a position of the bottom face of the second semi-insulating layer is lower than a position of an upper face of the second cladding layer, and is higher than a position of a bottom face of the first active layer.

5. A method of manufacturing an optical integrated semiconductor element on a semiconductor substrate, the semiconductor substrate including a first region acting as a laser element and a second region acting as a modulator, the first region and the second region being continuous along an optical axis direction of the laser element, the method comprising:
a step of forming a first cladding layer of a first conductive type in the first region and the second region on the semiconductor substrate;
a step of forming a first active layer on the first cladding layer;
a step of forming a second cladding layer of a second conductive type on the first active layer;
a step of removing the first active layer and the second cladding layer in the second region;
a step of forming a second active layer on the first cladding layer in the second region such that the first active layer and the second active layer are continuous along the optical axis direction of the laser element;
a step of forming a third cladding layer of the second conductive type on the second active layer in the second region such that the second cladding layer and the third cladding layer are continuous along the optical axis direction of the laser element;
a step of forming, in the first region, a first mesa constituted of the first cladding layer, the first active layer, and the second cladding layer and forming, in the second region, a second mesa constituted of the first cladding layer, the second active layer, and the third cladding such that the first mesa and the second mesa are continuous along the optical axis direction of the laser element, by etching a part of the first cladding layer, the first active layer, the second cladding layer, the second active layer, and the third cladding layer;
a step of forming a first semi-insulating layer on the first cladding layer and on both sides of the first mesa and both sides of the second mesa;
a step of forming an auxiliary cladding layer of the second conductive type on the first semi-insulating layer and on the first mesa and the second mesa;
a step of forming, on the first mesa, a third mesa that is constituted of the auxiliary cladding layer and has a larger width than the first mesa, by etching a part of the first semi-insulating layer and the auxiliary cladding layer in the first region, and forming, on the second mesa, a fourth mesa that is constituted of the auxiliary cladding layer and has a larger width than the second mesa such that the third mesa and the fourth mesa are continuous along the optical axis direction of the laser element, by etching a part of the first semi-insulating layer and the auxiliary cladding layer in the second region; and
a step of forming a second semi-insulating layer on the first semi-insulating layer and on both sides of the third mesa and both sides of the fourth mesa, wherein
a width of the third mesa is greater than a width of the fourth mesa.

6. The method of manufacturing the optical integrated semiconductor element according to claim 5, wherein
the first semi-insulating layer has a level difference on a surface thereof, and a bottom face of the second semi-insulating layer is in contact with a bottom face of the level difference, and
a position of the bottom face of the second semi-insulating layer is lower than a position of an upper face of the second cladding layer, and is higher than a position of a bottom face of the first active layer.
